(19) United States
(12) Patent Application Publication
(10) Pub. No.: US 2025/0240932 A1
(43) Pub. Date: Jul. 24, 2025

(54) SERVER COOLING SYSTEM

(71) Applicant: BITMAIN TECHNOLOGIES INC, Beijing (CN)

(72) Inventors: Hangkong HU, Beijing (CN); Shaoming HUANG, Beijing (CN); Hongbo ZENG, Beijing (CN); Mingliang HAO, Beijing (CN); Shengqiang XIAO, Beijing (CN); Chunlang RUAN, Beijing (CN); Pengfei ZHENG, Beijing (CN); Yurong PENG, Beijing (CN); Fengjie LI, Beijing (CN); Hongshan ZHU, Beijing (CN)

(21) Appl. No.: 19/067,441

(22) Filed: Feb. 28, 2025

Related U.S. Application Data
(63) Continuation of application No. PCT/CN2023/109644, filed on Jul. 27, 2023.

(30) Foreign Application Priority Data
Aug. 30, 2022 (CN) 202222298236.0

(51) Int. Cl. H05K 7/20

(52) U.S. Cl. CPC H05K 7/20836; H05K 7/20254; H05K 7/20263; H05K 7/20272; H05K 7/20281; H05K 7/20763

(57) ABSTRACT

A server cooling system relates to a technical field of server heat dissipation and solves problems of high manufacturing costs, large maintenance workload, and high energy consumption of existing server cooling systems. The server cooling system includes a flow divider, a heat exchange device, a first temperature sensor, a second temperature sensor, a control device, and a circulating pump. The server cooling system is configured to dissipate heat from a server cluster, and the cooling liquid is divided by the flow divider before the cooling liquid cools servers, such that the cooling liquid flows through each server in the server cluster through different pipelines, realizing centralized heat dissipation of the servers, reducing the manufacturing cost of the server cooling system, and lowering the maintenance workload and energy consumption of the server cooling system.

### CROSS-REFERENCE TO RELATED APPLICATIONS

The present application is a continuation of International Application No. PCT/CN2023/109644, filed on Jul. 27, 2023, which claims priority to Chinese Patent Application No. 202222298236.0, filed with China National Intellectual Property Administration on Aug. 30, 2022, entitled “Server Cooling System”. The afore-mentioned patent applications are hereby incorporated by reference in their entireties.

### TECHNICAL FIELD

The present application relates to the technical field of server heat dissipation, and in particular, to a server cooling system.

### BACKGROUND

A server generates a lot of heat when it is working. To ensure normal running of the server, the server needs to undergo heat dissipation. The inventor realized that, at present, layout of the server is scattered, and it is necessary to dissipate heat separately for each server, which will lead to high manufacturing costs, large maintenance workload and high energy consumption of the server cooling system.

### SUMMARY

Embodiments of the present application provides a server cooling system, which aims to solve problems of high manufacturing costs, large maintenance workload, and high energy consumption of existing server cooling systems. The server cooling system includes:
a flow divider, including one first liquid inlet and a plurality of first liquid outlets, the first liquid outlets being configured for connecting with server liquid inlets;
a heat exchange device, including a second liquid inlet and a second liquid outlet, the second liquid inlet being configured for connecting with a server liquid outlet, and the second liquid outlet being connected with the first liquid inlet through a pipeline;
a first temperature sensor, arranged in a pipeline between the second liquid inlet and the server liquid outlet, and configured for detecting a temperature of a cooling liquid flowing into the heat exchange device;
a second temperature sensor, arranged in a pipeline between the second liquid outlet and the first liquid inlet, and configured for detecting a temperature of a cooling liquid flowing out of the heat exchange device;
a control device, connected with the first temperature sensor, the second temperature sensor and the heat exchange device, the control device being configured for obtaining a temperature detected by the first temperature sensor and a temperature detected by the second temperature sensor, and controlling the heat exchange device to perform a cooling treatment on the cooling liquid according to the temperature detected by the first temperature sensor and the temperature detected by the second temperature sensor; and
a circulating pump, arranged in a pipeline between the server liquid outlet and the second liquid inlet.

In one possible embodiment, the heat exchange device includes:
a plate heat exchanger, including the second liquid inlet and the second liquid outlet;
a first electric three-way valve, arranged in a pipeline between the first temperature sensor and the second liquid inlet;
a cooling liquid diverting pipeline, one end of the cooling liquid diverting pipeline being connected with a liquid outlet of the first electric three-way valve, and the other end of the cooling liquid diverting pipeline being connected with a pipeline between the second liquid outlet and the second temperature sensor;
where the control device controls opening of the first electric three-way valve according to the temperature detected by the first temperature sensor and the temperature detected by the second temperature sensor.

In one possible embodiment, the heat exchange device includes:
a cooling tower, including a fan, the control device controlling a rotation speed of the fan of the cooling tower according to the temperature detected by the first temperature sensor and the temperature detected by the second temperature sensor.

In one possible embodiment, the server cooling system further includes:
a liquid adding piping, including a liquid replenishing pump, an external interface, and a pipeline for connecting the liquid replenishing pump and the external interface, the liquid adding piping being configured to add a cooling liquid to the server cooling system;
a cooling liquid container, including a first liquid charging port and a liquid discharging port, the first liquid charging port being communicated with a pipeline at a liquid discharge end of the liquid replenishing pump through a first pipeline, and the liquid discharging port being communicated with a pipeline between a liquid inlet end of the liquid replenishing pump and the external interface through a second pipeline;
where the first pipeline is configured for adding the cooling liquid to the cooling liquid container, and the second pipeline is configured for discharging the cooling liquid from the cooling liquid container or adding the cooling liquid to the server cooling system.

In one possible embodiment, the server cooling system further includes:
an evacuation pipeline, one end of the evacuation pipeline being connected to the external interface, and the other end of the evacuation pipeline being connected to a pipeline between the server liquid outlet and the second liquid inlet or a pipeline between the second liquid outlet and the first liquid inlet, and the evacuation pipeline being configured for evacuating the pipeline of the server cooling system.

In one possible embodiment, the server cooling system further includes:
a first pressure sensor, arranged in a pipeline between the second liquid inlet and the liquid outlet of the server for detecting a pressure of the cooling liquid flowing into the heat exchange device;
a second pressure sensor, arranged in a pipeline between the second liquid outlet and the first liquid inlet for detecting a pressure of the cooling liquid flowing out of the heat exchange device.

In one possible embodiment, the server cooling system further includes:
an expansion tank, connected with a pipeline between the server liquid outlet and the circulating pump through a pipeline.

In one possible embodiment, the cooling liquid container further includes a second liquid charging port, and the server cooling system further includes:
a safety valve, one end of the safety valve being connected to a pipeline between the second pressure sensor and the first liquid inlet through a pipeline, and the other end of the safety valve being connected to the second liquid charging port through a pipeline;
where when the pressure in the pipeline of the server cooling system is greater than a set pressure of the safety valve, the safety valve is opened to discharge part of the cooling liquid in the pipeline of the server cooling system into the cooling liquid container.

In one possible embodiment, the server cooling system further includes:
a second electric three-way valve, arranged in a pipeline between the circulating pump and the second liquid inlet, the second electric three-way valve being connected with the control device;
a short-circuit pipeline, one end of the short-circuit pipeline being connected with a liquid outlet of the second electric three-way valve, and the other end of the short-circuit pipeline being connected with a pipeline between the second liquid outlet and the second temperature sensor;
where, when an external temperature is lower than a preset temperature, the control device controls an opening of the second electric three-way valve to allow the cooling liquid to flow through the short-circuit pipeline.

In one possible embodiment, the server cooling system further includes:
a third electric three-way valve, a liquid inlet of the third electric three-way valve being connected to the circulating pump through a pipeline, one liquid outlet of the third electric three-way valve being connected to a liquid inlet of the first electric three-way valve through a pipeline, the other liquid outlet of the third electric three-way valve being connected to the second liquid inlet of the cooling tower through a pipeline, and the third electric three-way valve being connected with the control device;
and/or the server cooling system further includes a fifth valve and a sixth valve, the fifth valve being configured for controlling the cooling liquid to flow through the plate heat exchanger, and the sixth valve being configured for controlling the cooling liquid to flow through the cooling tower.

Embodiments of the present application provides a server cooling system, including a flow divider, a heat exchange device, a first temperature sensor, a second temperature sensor, a control device, and a circulating pump. The server cooling system is configured to dissipate heat from a server cluster, and the cooling liquid is divided by the flow divider before the cooling liquid cools servers, such that the cooling liquid flows through each server in the server cluster through different pipelines, realizing centralized heat dissipation of the servers, reducing the manufacturing cost of the server cooling system, and reducing the maintenance workload and energy consumption of the server cooling system.

### BRIEF DESCRIPTION OF DRAWINGS

In order to more clearly explain technical solutions of embodiments of the present application, the drawings required to be used in the description of embodiments will be briefly introduced below. Obviously, the drawings in the following description are some embodiments of the present application. For those skilled in the art, other drawings can also be obtained based on these drawings without creative efforts.

FIG. 1 is a schematic block diagram of a structure of a server cooling system provided in an embodiment of the present application.

FIG. 2 is a schematic block diagram of a structure of further server cooling system provided in an embodiment of the present application.

FIG. 3 is a schematic block diagram of a structure of yet further server cooling system provided in an embodiment of the present application.

FIG. 4 is a schematic block diagram of a structure of still further server cooling system provided in an embodiment of the present application.

### DESCRIPTION OF EMBODIMENTS

Technical solutions in the embodiments of the present application will be clearly and completely described below in combination with the drawings in the embodiments of the present application. Obviously, the embodiments described are only part of the embodiments of the present application, but not all embodiments. Based on the embodiments in the present application, all other embodiments acquired by those skilled in the art without creative labor fall within the scope of protection in the present application.

It should be noted that all directional indications (such as up, down, left, right, front, back . . . ) in the embodiments of the present application are only used to explain the relative position relationship, motion, etc. between various components in some specific posture. If the specific posture changes, the directional indication will change accordingly.

It should also be noted that when a component is referred to be “fixed” or “arranged” on another component, it may be directly on the other component or there may be an intermediate component at the same time. When a component is referred to be “connected” to another component, it may be directly connected to another component or indirectly connected to another component through an intermediate component.

In addition, descriptions in the present application referring to “first”, “second”, etc., are only used for descriptive purposes and are not to be understood as indicating or implying its relative importance or as implicitly indicating the quantity of the technical features indicated. Thus, a feature defined by “first” or “second” may explicitly or implicitly include at least one feature. Besides, the technical solutions between various embodiments may be combined with each other, but they shall be based on realization by those skilled in the art. When the combination of technical solutions contradicts each other or cannot be realized, it shall be considered that such combination of technical solutions does not exist and is not within the scope of protection required by the present application.

Some embodiments of the present application are described in detail below in combination with the drawings. Without conflicting, the following embodiments and the features in the embodiments may be combined with each other.

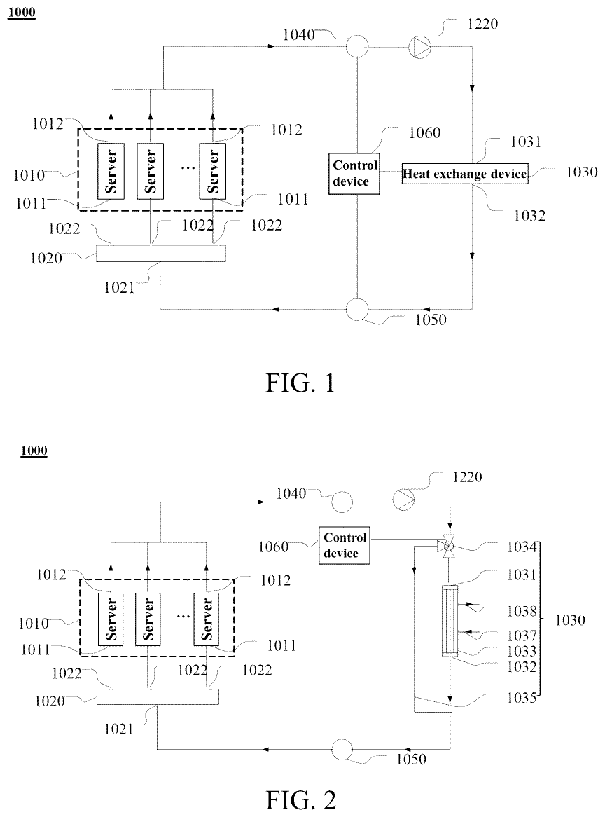

Please refer to FIG. 1, FIG. 1 is a schematic block diagram of a structure of a server cooling system 1000 provided in an embodiment of the present application. The server cooling system 1000 provided by the embodiment of the present application includes at least one flow divider 1020, a heat exchange device 1030, a first temperature sensor 1040, a second temperature sensor 1050, a control device 1060, and a circulating pump 1220. The server cooling system provided by the embodiment of the present application is used to dissipate heat from a server cluster, and cooling liquid is divided by the flow divider 1020 before the cooling liquid cools servers, such that the cooling liquid flows through each server in the server cluster 1010 through different pipelines, realizing centralized heat dissipation of the servers, reducing the manufacturing cost of the server cooling system 1000, and reducing the maintenance workload and energy consumption of the server cooling system 1000.

Where, the flow divider 1020 includes one first liquid inlet 1021 and a plurality of first liquid outlets 1022, and the first liquid outlets 1022 are configured for connecting with server liquid inlets 1011 respectively.

Where, the heat exchange device 1030 includes a second liquid inlet 1031 and a second liquid outlet 1032. The second liquid inlet 1031 is used to connect with server liquid outlets 1012, and the second liquid outlet 1032 is connected with the first liquid inlet 1021 through a pipeline. It can be understood that multiple pipelines respectively connecting the multiple server liquid outlets 1012 with the second liquid outlet 1032 are converged into one pipeline.

Where, the first temperature sensor 1040 is arranged in the pipeline between the second liquid inlet 1031 and the server liquid outlets 1012. The first temperature sensor 1040 is used to detect the temperature of the cooling liquid flowing into the heat exchange device 1030.

Where, the second temperature sensor 1050 is arranged in the pipeline between the second liquid outlet 1032 and the first liquid inlet 1021. The second temperature sensor 1050 is used to detect the temperature of the cooling liquid flowing out of the heat exchange device 1030.

Where, the control device 1060 is connected to the first temperature sensor 1040, the second temperature sensor 1050 and the heat exchange device 1030. The control device 1060 is used to obtain the temperature detected by the first temperature sensor 1040 and the temperature detected by the second temperature sensor 1050, and control the heat exchange device 1030 to perform cooling treatment on the cooling liquid according to the temperature detected by the first temperature sensor 1040 and the temperature detected by the second temperature sensor 1050.

Where, the circulating pump 1220 is arranged in a pipeline between the server liquid outlet 1012 and the second liquid inlet 1031. The circulating pump 1220 is used to drive the circulation of cooling liquid in the pipelines of the server cooling system 1000.

In some embodiments, as shown in FIG. 2, the heat exchange device 1030 includes a plate heat exchanger 1033, a first electric three-way valve 1034, and a cooling liquid diverting pipeline 1035. Where, the plate heat exchanger 1033 includes a second liquid inlet 1031 and a second liquid outlet 1032; the first electric three-way valve 1034 is arranged in the pipeline between the first temperature sensor 1040 and the second liquid inlet 1031; one end of the cooling liquid diverting pipeline 1035 is connected with a liquid outlet of the first electric three-way valve 1034, and the other end of the cooling liquid diverting pipeline 1035 is connected with the pipeline between the second liquid outlet 1032 and the second temperature sensor 1050.

The control device 1060 controls opening of the first electric three-way valve 1034 according to the temperature detected by the first temperature sensor 1040 and the temperature detected by the second temperature sensor 1050, to adjust a flow rate of the cooling liquid flowing through the flow plate heat exchanger 1033 and a flow rate of the cooling liquid flowing through the cooling liquid diverting pipeline 1035, so that a temperature of the cooling liquid flowing into the servers is kept within a certain range.

It is understood that the first electric three-way valve 1034 includes one liquid inlet and two liquid outlets. The liquid inlet of the first electric three-way valve 1034 is connected with the server liquid outlet 1012 through a pipeline; and one liquid outlet of the first electric three-way valve 1034 is connected with one end of the cooling liquid diverting pipeline 1035, and the other liquid outlet of the first electric three-way valve 1034 is connected with a second liquid inlet 1031 through a pipeline. The cooling liquid with higher temperature that flows through the cooling liquid diverting pipeline 1035 is converged with the cooling liquid with lower temperature that flows out of the second liquid outlet 1032 of the plate heat exchanger 1033, to maintain the temperature of the cooling liquid flowing into the server to be within a certain range.

In some embodiments, as shown in FIG. 2, the plate heat exchanger includes a third pipeline 1037 and a fourth pipeline 1038. The third pipeline 1037 is connected to a municipal water supply end, and the fourth pipeline 1038 is connected to a municipal water consumption end. In the present embodiment, the municipal water source may be heated by the plate heat exchanger 1033.

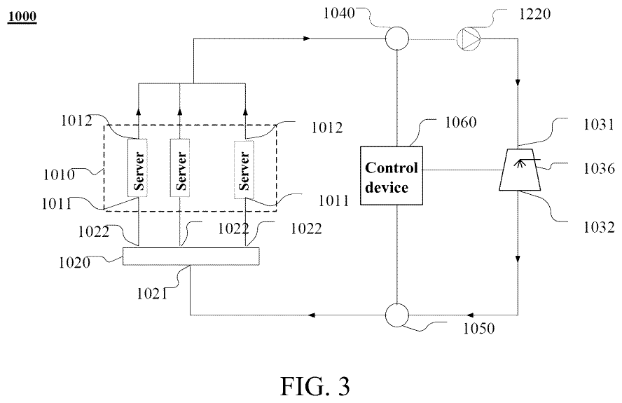

In some embodiments, as shown in FIG. 3, the heat exchange device 1030 includes a cooling tower 1036. The cooling tower 1036 includes a fan, and the control device 1060 controls the rotation speed of the fan of the cooling tower 1036 according to the temperature detected by the first temperature sensor 1040 and the temperature detected by the second temperature sensor 1050, and adjusts a heat dissipation rate to keep the temperature of the cooling liquid flowing into the server within a certain range.

It is understood that in the present embodiment, the second liquid inlet 1031 and the second liquid outlet 1032 are located in the cooling tower 1036.

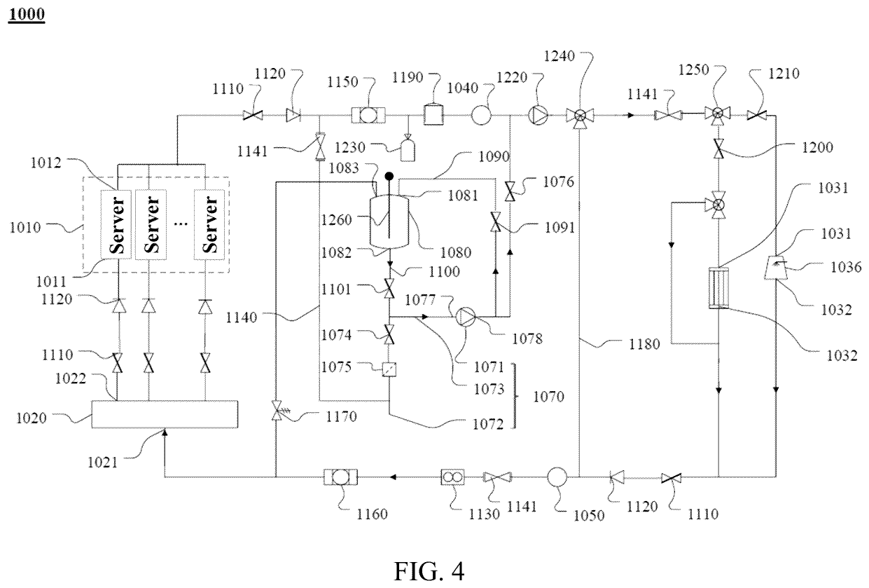

In some embodiments, as shown in FIG. 4, the heat exchange device 1030 includes not only the heat exchange devices concerning the plate heat exchanger 1033, the first electric three-way valve 1034 and the cooling liquid diverting pipeline 1035 in the above embodiments, but also the heat exchange device concerning the cooling tower 1036 in the above embodiments. In the present embodiment, the server cooling system 1000 further includes a fifth valve 1200 and a sixth valve 1210. The fifth valve 1200 is used to control the flow of cooling liquid through the plate heat exchanger 1033, and the sixth valve 1210 is used to control the flow of cooling liquid through the cooling tower 1036. When the cooling liquid source is sufficient, the plate heat exchanger 1033 is used to cool the cooling liquid, the fifth valve 1200 is opened and the sixth valve 1210 is closed. For example, the cooling liquid source is water from large rivers and streams. When the cooling liquid source is limited, the cooling tower 1036 is used to cool the cooling liquid, the fifth valve 1200 is closed and the sixth valve 1210 is opened. For example, the cooling liquid is ultrapure water, ethanol, ethylene glycol, glycerol, etc., and there is no limitation to the type of cooling liquid, as long as it can cool the liquid of the server. The present embodiment may increase the flexibility of use of the server cooling system 1000.

In some embodiments, as shown in FIG. 4, the server cooling system 1000 also includes a third electric three-way valve 1250; and a liquid inlet of the third electric three-way valve 1250 is connected with the circulating pump 1220 through a pipeline, one liquid outlet of the third electric three-way valve 1250 is connected with the liquid inlet of the first electric three-way valve 1034 through a pipeline, the other liquid outlet of the third electric three-way valve 1250 is connected with the second liquid inlet 1031 of the cooling tower 1036 through a pipeline, and the third electric three-way valve 1250 is connected with the control device 1060 (not shown in FIG. 4). In the present embodiment, the control device 1060 can control a cooling mode of the heat exchange device 1030 for cooling the cooling liquid according to the temperature difference between the temperature detected by the first temperature sensor 1050 and the temperature detected by the second temperature sensor 1060. In particular, the cooling mode includes three types of cooling modes, i.e., cooling by a plate heat exchanger 1033, cooling by a cooling tower 1036, and simultaneous cooling by a plate heat exchanger 1033 and a cooling tower 1036. It can be understood that the control device 1060 adopts a cooling mode that controls the heat exchange device 1030 to cool the cooling liquid by controlling the opening of the third electric three-way valve 1250.

Exemplarily, when the temperature difference is less than 20° C., the plate heat exchanger 1033 is used for cooling, and the control device 1060 controls the opening of the third electric three-way valve 1250 to allow all cooling liquid to flow through the plate heat exchanger 1033. When the temperature difference is greater than 50° C., the plate heat exchanger 1033 and the cooling tower 1036 are used for cooling simultaneously, the control device 1060 controls the opening of the third electric three-way valve 1250 according to the specific value of the temperature difference, so that one part of the cooling liquid flows through the plate heat exchanger 1033 and the other part of the cooling liquid flows through the cooling tower 1033. When the temperature difference is between 20° C. and 50° C., the cooling tower 1036 is used for cooling, and the control device 1060 controls the opening of the third electric three-way valve 1250 to allow all cooling liquid to flow through the cooling tower 1036.

In some embodiments, as shown in FIG. 4, at least one of the pipeline between the second liquid outlet 1032 and the first liquid inlet 1021, the pipeline between the first liquid outlet 1022 and the server liquid inlet 1011, and the pipeline between the server liquid outlet 1012 and the second liquid inlet 1031 is provided with a valve 1110 and a check valve 1120, the valve 1110 is used to control flow and interruption of the cooling liquid in the pipelines, and the check valve 1120 is used to prevent the backflow of the cooling liquid.

In some embodiments, as shown in FIG. 4, the server cooling system 1000 also includes a liquid adding piping 1070 and a cooling liquid container 1080. The liquid adding piping 1070 includes a liquid replenishing pump 1071, an external interface 1072 and a pipeline 1073 connecting the liquid replenishing pump 1071 and an external interface 1072. The liquid adding piping 1070 is used to add the cooling liquid to the server cooling system 1000; the cooling liquid container 1080 includes a first liquid charging port 1081 and a liquid discharging port 1082. The first liquid charging port 1081 is communicated with a pipeline at a liquid outlet end 1078 of the liquid replenishing pump 1071 through a first pipeline 1090, and the liquid discharging port 1082 is connected to a pipeline between the liquid inlet end 1077 of the liquid replenishing pump 1071 and the external interface 1072 through a second pipeline 1100. The first pipeline 1090 is used to add the cooling liquid to the cooling liquid container 1080, and the second pipeline 1100 is used to discharge the cooling liquid from the cooling liquid container 1080 or to add the cooling liquid to the server cooling system 1000. The present embodiment can not only add the cooling liquid to the server cooling system 1000, but also replenish the server cooling system 1000 with the cooling liquid when the liquid in the pipelines of the server cooling system 1000 is insufficient.

It should be noted that the pipeline at the liquid outlet end 1078 of the liquid replenishing pump 1071 is connected with a pipeline between the server liquid outlet 1012 and the circulating pump 1220 to realize the liquid replenishment of the server cooling system 1000.

Specifically, as shown in FIG. 4, the first pipeline 1090 is provided with a first valve 1091, the second pipeline 1100 is provided with a second valve 1101, the pipeline 1073 between the liquid inlet end 1077 of the liquid replenishing pump 1071 and the external interface 1072 is provided with a third valve 1074, and a pipeline at the liquid outlet end 1078 of the liquid replenishing pump 1071 is provided with a fourth valve 1076. The first pipeline 1090 is connected with a pipeline between the liquid outlet end 1078 of the liquid replenishing pump 1071 and the fourth valve 1076; and the second pipeline 1100 is communicated with a pipeline between the liquid inlet end 1077 of the liquid replenishing pump 1071 and the third valve 1074. When there is no cooling liquid in the server cooling system 1000, the staff will connect the external interface 1072 with the cooling liquid source, such as a faucet, the third valve 1074 and the fourth valve 1076 are opened, and the first valve 1091 and the second valve 1101 are closed, the cooling liquid is added to the server cooling system 1000 by flowing through the liquid adding piping 1070 and the pipeline at the liquid outlet end 1078 of the liquid replenishing pump 1071.

It can be understood that the temperature of the cooling liquid rises after it flows through the server, which may lead to evaporation of the cooling liquid, resulting in insufficient cooling liquid flow in the pipelines of the server cooling system 1000, and the need to replenish the server cooling system 1000 with the cooling liquid. Specifically, as shown in FIG. 4, the cooling liquid system further includes a flow sensor 1130, which is used to detect the flow rate of liquid in the pipeline. The flow sensor 1130 is arranged in the pipeline between the second liquid outlet 1032 and the first liquid inlet 1021. The flow sensor 1130 is connected to the control device 1060 (not shown). The control device 1060 is used to obtain the flow rate of liquid in the pipeline detected by the flow sensor 1130 in real time. When the liquid flow rate value detected by the flow sensor 1130 is less than a preset liquid flow rate value, the control device 1060 controls the second valve 1101 and the fourth valve 1076 to open and the first valve 1091 and the third valve 1074 to close, allowing the cooling liquid in the cooling liquid container 1080 to flow through the second pipeline 1100, the liquid adding piping 1070 and the pipeline of the liquid outlet end 1078 of the liquid replenishing pump 1071 to replenish the cooling liquid for the server cooling system 1000.

It can be understood that when the cooling liquid container 1080 is charged with the cooling liquid, the third valve 1074 and the first valve 1091 are opened, and the second valve 1101 and the fourth valve 1076 are closed.

In some embodiments, as shown in FIG. 4, the pipeline between the liquid inlet end 1077 of the liquid replenishing pump 1071 and the external interface 1072 is provided with a filter 1075, which is used to filter impurities of the cooling liquid, such as sediment, iron filings, etc., to prevent impurities from flowing into the pipeline and causing pipeline obstruction.

In some embodiments, as shown in FIG. 4, the server cooling system 1000 also includes an evacuation pipeline 1140. One end of the evacuation pipeline 1140 is connected to the external interface 1072 through a pipeline; and the other end of the evacuation pipeline 1140 is connected to the pipeline between the server liquid outlet 1012 and the second liquid inlet 1031, or to the pipeline between the second liquid outlet 1032 and first liquid inlet 1021. The evacuation pipeline 1140 is used to empty the pipelines of the server cooling system 1000.

Specifically, the evacuation pipeline 1140 is provided with an evacuation valve 1141. It can be understood that in order to improve the effect of emptying the pipelines of the server cooling system 1000, the evacuation valve 1141 may be provided in the pipeline between the server liquid outlet 1012 and the second liquid inlet 1031, and in the pipeline between the second liquid outlet 1032 and the first liquid inlet 1021.

It can be understood that the external interface 1072 is not connected to any cooling liquid source when the pipeline of the server cooling system 1000 is subjected to evacuation. The cooling liquid flowing out of the external interface 1072 can be diverted to a waste liquid pool, or the cooling liquid flowing out of the external interface 1072 can be collected in a waste liquid container.

In some embodiments, as shown in FIG. 4, the server cooling system 1000 also includes a first pressure sensor 1150, which is located in the pipeline between the second liquid inlet 1031 and the server liquid outlet 1012, to detect the pressure of the cooling liquid flowing into the heat exchange device 1030. Specifically, the first pressure sensor 1150 is connected with the control device 1060, and the control device 1060 is used to obtain a pressure detected by the first pressure sensor 1150. When the pressure detected by the first pressure sensor 1150 is less than a preset pressure, the control device 1060 controls the second valve 1101 and the fourth valve 1076 to open, and the first valve 1091 and the third valve 1074 to close, so that the cooling liquid in the cooling liquid container 1080 flows through the second pipeline 1100, the liquid adding piping 1070, and the pipeline at the liquid outlet end 1078 of the liquid replenishing pump to replenish the cooling liquid for the server cooling system 1000.

In some embodiments, as shown in FIG. 4, the server cooling system 1000 further includes a second pressure sensor 1160 arranged in the pipeline between the second liquid outlet 1032 and the first liquid inlet 1021, to detect the pressure of the cooling liquid flowing out of the heat exchange device 1030. Specifically, the second pressure sensor 1160 is connected to the control device 1060, and the control device 1060 is used to obtain the pressure detected by the second pressure sensor 1160. When the pressure detected by the second pressure sensor 1160 is greater than a preset pressure, the control device 1060 controls the circulating pump 1220 to be closed, thereby preventing excessive pressure of the cooling liquid flowing into the server and causing damage to the server.

In some embodiments, as shown in FIG. 4, the server cooling system 1000 also includes an expansion tank 1230, which is connected by a pipeline between the server liquid outlet 1012 and the circulating pump 1220; and the expansion tank 1230 is used to regulate the pressure of the liquid in the pipeline of the server cooling system 1000, to maintain a stability of a circulation of the cooling liquid in the pipeline of the server cooling system 1000.

In some embodiments, as shown in FIG. 4, the cooling liquid container 1080 also includes a second liquid charging port 1083, and the server cooling system 1000 also includes a safety valve 1170. One end of the safety valve 1170 is connected with a pipeline between the second pressure sensor 1160 and the first liquid inlet 1021 through a pipeline, and the other end of the safety valve 1170 is connected with the second liquid charging port 1083 through a pipeline. The safety valve 1170 opens when the pressure in the pipeline of the server cooling system 1000 is greater than the set pressure of the safety valve 1170, to discharge part of the cooling liquid in the pipeline of the server cooling system 1000 to the cooling liquid container 1080, maintaining a normal operation of the server cooling system 1000 and preventing the failure thereof.

In some embodiments, as shown in FIG. 4, the server cooling system 1000 also includes a level sensor 1260, which is configured to detect the level of the cooling liquid in the cooling liquid container 1080.

In some embodiments, as shown in FIG. 4, the server cooling system 1000 also includes a second electric three-way valve 1240 and a short circuit pipeline 1180, where the second electric three-way valve 1240 is arranged in a pipeline between the circulating pump 1220 and the second liquid inlet 1031, and the second electric three-way valve 1240 is connected to the control device 1060 (not shown in FIG. 4). One end of the short circuit pipeline 1180 is connected with the liquid outlet of the second electric three-way valve 1240. The other end of the short circuit pipeline 1180 is connected with the pipeline between the second liquid outlet 1032 and the second temperature sensor 1050. When the external temperature is lower than the preset temperature, the control device 1060 makes the cooling liquid flow through the short circuit pipeline 1180 by controlling the opening of the second electric three-way valve 1240.

It should be noted that making the cooling liquid flow through the short circuit pipeline 1180 in the present embodiment means that making all the cooling liquid in the pipelines of the server cooling system 1000 flow through the short circuit pipeline 1180.

In some embodiments, the server cooling system 1000 further includes a degassing tank 1190 arranged in the pipeline between the server liquid outlet 1012 and the second liquid inlet 1031. The degassing tank 1190 is configured to remove gas in the cooling liquid.

The above is only the specific implementation of the present application, but the scope of protection of the present application is not limited to this. Any skilled in the art familiar with the technical field can easily think of various equivalent modifications or replacements within the technical scope disclosed in the present application, and all these modifications or replacements shall be covered by the scope of protection of the present application. Therefore, the scope of protection in the present application shall be governed by the scope of protection of the claims.

What is claimed is:

1. A server cooling system, wherein the server cooling system comprises:
a flow divider, comprising one first liquid inlet and a plurality of first liquid outlets, the first liquid outlets being configured for connecting with server liquid inlets respectively;
a heat exchange device, comprising a second liquid inlet and a second liquid outlet, the second liquid inlet being configured for connecting with a server liquid outlet, and the second liquid outlet being connected with the first liquid inlet through a pipeline;
a first temperature sensor, arranged in a pipeline between the second liquid inlet and the server liquid outlet, and configured for detecting a temperature of a cooling liquid flowing into the heat exchange device;
a second temperature sensor, arranged in a pipeline between the second liquid outlet and the first liquid inlet, and configured for detecting a temperature of a cooling liquid flowing out of the heat exchange device;
a control device, connected with the first temperature sensor, the second temperature sensor and the heat exchange device, the control device being configured for obtaining a temperature detected by the first temperature sensor and a temperature detected by the second temperature sensor, and controlling the heat exchange device to perform a cooling treatment on the cooling liquid according to the temperature detected by the first temperature sensor and the temperature detected by the second temperature sensor; and
a circulating pump, arranged in a pipeline between the server liquid outlet and the second liquid inlet.

2. The server cooling system according to claim 1, wherein the heat exchange device comprises:
a plate heat exchanger, comprising the second liquid inlet and the second liquid outlet;
a first electric three-way valve, arranged in a pipeline between the first temperature sensor and the second liquid inlet;
a cooling liquid diverting pipeline, one end of the cooling liquid diverting pipeline being connected with a liquid outlet of the first electric three-way valve, and the other end of the cooling liquid diverting pipeline being connected with a pipeline between the second liquid outlet and the second temperature sensor;
wherein the control device controls opening of the first electric three-way valve according to the temperature detected by the first temperature sensor and the temperature detected by the second temperature sensor.

3. The server cooling system according to claim 1, wherein the heat exchange device comprises:
a cooling tower, comprising a fan, the control device controlling a rotation speed of the fan of the cooling tower according to the temperature detected by the first temperature sensor and the temperature detected by the second temperature sensor.

4. The server cooling system according to claim 1, wherein the server cooling system further comprises:
a liquid adding piping, comprising a liquid replenishing pump, an external interface, and a pipeline for connecting the liquid replenishing pump and the external interface, the liquid adding piping being configured to add a cooling liquid to the server cooling system;
a cooling liquid container, comprising a first liquid charging port and a liquid discharging port, the first liquid charging port being communicated with a pipeline at a liquid discharge end of the liquid replenishing pump through a first pipeline, and the liquid discharging port being communicated with a pipeline between a liquid inlet end of the liquid replenishing pump and the external interface through a second pipeline;
wherein the first pipeline is configured for adding the cooling liquid to the cooling liquid container, and the second pipeline is configured for discharging the cooling liquid from the cooling liquid container or adding the cooling liquid to the server cooling system.

5. The server cooling system according to claim 4, wherein the server cooling system further comprises:
an evacuation pipeline, one end of the evacuation pipeline being connected to the external interface, and the other end of the evacuation pipeline being connected to a pipeline between the server liquid outlet and the second liquid inlet or a pipeline between the second liquid outlet and the first liquid inlet, and the evacuation pipeline being configured for evacuating the pipeline of the server cooling system.

6. The server cooling system according to claim 4, wherein the server cooling system further comprises:
a first pressure sensor, arranged in a pipeline between the second liquid inlet and the server liquid outlet for detecting a pressure of the cooling liquid flowing into the heat exchange device; and/or
a second pressure sensor, arranged in a pipeline between the second liquid outlet and the first liquid inlet for detecting a pressure of the cooling liquid flowing out of the heat exchange device.

7. The server cooling system according to claim 1, wherein the server cooling system further comprises:
an expansion tank, connected with a pipeline between the server liquid outlet and the circulating pump through a pipeline.

8. The server cooling system according to claim 6, wherein the cooling liquid container further comprises a second liquid charging port, and the server cooling system further comprises:
a safety valve, one end of the safety valve being connected to a pipeline between the second pressure sensor and the first liquid inlet through a pipeline, and the other end of the safety valve being connected to the second liquid charging port through a pipeline;
wherein when the pressure in the pipeline of the server cooling system is greater than a set pressure of the safety valve, the safety valve is opened to discharge part of the cooling liquid in the pipeline of the server cooling system into the cooling liquid container.

9. The server cooling system according to claim 1, wherein the server cooling system further comprises:
a second electric three-way valve, arranged in a pipeline between the circulating pump and the second liquid inlet, the second electric three-way valve being connected with the control device;
a short-circuit pipeline, one end of the short-circuit pipeline being connected with a liquid outlet of the second electric three-way valve, and the other end of the short-circuit pipeline being connected with a pipeline between the second liquid outlet and the second temperature sensor;
wherein, when an external temperature is lower than a preset temperature, the control device controls an opening of the second electric three-way valve to allow the cooling liquid to flow through the short-circuit pipeline.

10. The server cooling system according to claim 2, wherein the server cooling system further comprises:
a third electric three-way valve, a liquid inlet of the third electric three-way valve being connected to the circulating pump through a pipeline, one liquid outlet of the third electric three-way valve being connected to a liquid inlet of the first electric three-way valve through a pipeline, and the other liquid outlet of the third electric three-way valve being connected to the second liquid inlet of the cooling tower through a pipeline;
and/or, the server cooling system further comprises a fifth valve and a sixth valve, the fifth valve being configured for controlling the cooling liquid to flow through the plate heat exchanger, and the sixth valve being configured for controlling the cooling liquid to flow through the cooling tower.

11. The server cooling system according to claim 3, wherein the server cooling system further comprises:
a third electric three-way valve, a liquid inlet of the third electric three-way valve being connected to the circulating pump through a pipeline, one liquid outlet of the third electric three-way valve being connected to a liquid inlet of the first electric three-way valve through a pipeline, and the other liquid outlet of the third electric three-way valve being connected to the second liquid inlet of the cooling tower through a pipeline;
and/or, the server cooling system further comprises a fifth valve and a sixth valve, the fifth valve being configured for controlling the cooling liquid to flow through the plate heat exchanger, and the sixth valve being configured for controlling the cooling liquid to flow through the cooling tower.
